(19) United States
(12) Patent Application Publication
(10) Pub. No.: US 2011/0174526 A1
(43) Pub. Date: Jul. 21, 2011

(54) CIRCUIT MODULE

(75) Inventors: Yuji TAKEMATSU, Nagaokakyo-shi (JP); Koji FURUTANI, Nagaokakyo-shi (JP)

(73) Assignee: MURATA MANUFACTURING CO., LTD., Nagaokakyo-shi (JP)

(21) Appl. No.: 13/005,634

(22) Filed: Jan. 13, 2011

(30) Foreign Application Priority Data
Jan. 15, 2010 (JP) 2010-006364

(51) Int. Cl. H05K 1/00

(52) U.S. Cl. 174/258

(57) ABSTRACT

A circuit board includes a recess in a principal surface thereof. An IC chip is mounted in the recess. An insulating resin is filled in the recess. Via-hole conductors are provided in the insulating resin. A ground electrode covers the recess filled with the insulating resin. First ends of the via-hole conductors are in contact with the ground electrode. Second ends of the via-hole conductors are in contact with the IC chip.

### BACKGROUND OF THE INVENTION

1. Field of the Invention

The present invention relates to circuit modules, and particularly, to a circuit module including an electronic component mounted on a circuit board.

2. Description of the Related Art

An example of a known hybrid circuit module is described in Japanese Unexamined Patent Application Publication No. 11-220226. The hybrid module includes a circuit board, a circuit component, a thermal conductive resin, and a heat sink. The circuit board is a substrate including an electric circuit provided therein. The circuit board includes a recess in a back side thereof. The circuit component is, for example, a semiconductor integrated circuit and is mounted in the recess. The heat sink is arranged to cover the recess. The thermal conductive resin is disposed between the heat sink and the circuit component. In the hybrid module having the configuration described above, heat from the circuit component is dissipated outside the hybrid module through the thermal conductive resin and the heat sink. Thus, the hybrid module has excellent thermal dissipation performance.

However, in the hybrid module described in Japanese Unexamined Patent Application Publication No. 11-220226, the circuit component cannot be securely attached to the circuit board. Specifically, the thermal conductive resin is provided only between the heat sink and the circuit component. This is because if the recess is entirely filled with the thermal conductive resin, heat from the circuit component is transferred to the inside of the circuit board and deforms the circuit board. To prevent this, an empty space is provided around the circuit component. Therefore, the circuit component is not securely attached to the circuit board. As a result, an external shock to the hybrid module may cause a disconnection between the circuit board and the circuit component.

### SUMMARY OF THE INVENTION

To overcome the problems described above, preferred embodiments of the present invention provide a circuit module having excellent thermal dissipation performance and in which an electronic component (circuit component) is securely attached to a circuit board.

According to a preferred embodiment of the present invention, a circuit module preferably includes a circuit board including a recess in a principal surface thereof, an electronic component mounted in the recess, an insulating resin filled in the recess, and a via-hole conductor provided in the insulating resin. In the circuit module, one end of the via-hole conductor is preferably exposed from the insulating resin, and the other end of the via-hole conductor is preferably in contact with the electronic component.

Preferred embodiments of the present invention provide excellent thermal dissipation performance and enable the electronic component (circuit component) to be securely attached to the circuit board.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1A and FIG. 1B are external perspective views of a circuit module according to a preferred embodiment of the present invention.

FIG. 2 is an exploded perspective view of the circuit module illustrated in FIG. 1A and FIG. 1B.

FIG. 3 is a cross-sectional structural view taken along line III-III in the circuit module of FIG. 1A.

FIG. 4 is an exploded perspective view illustrating a circuit board of the circuit module of FIG. 1A and FIG. 1B.

### DETAILED DESCRIPTION OF THE PREFERRED EMBODIMENTS

Hereinafter, a circuit module according to preferred embodiments of the present invention will be described with reference to the drawings.

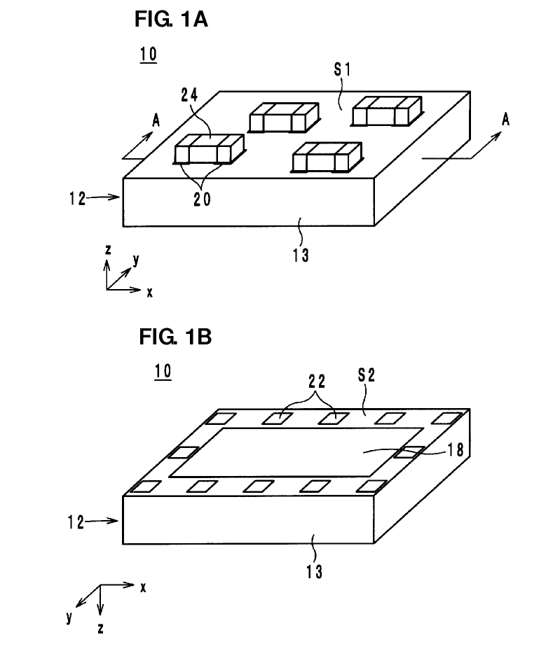

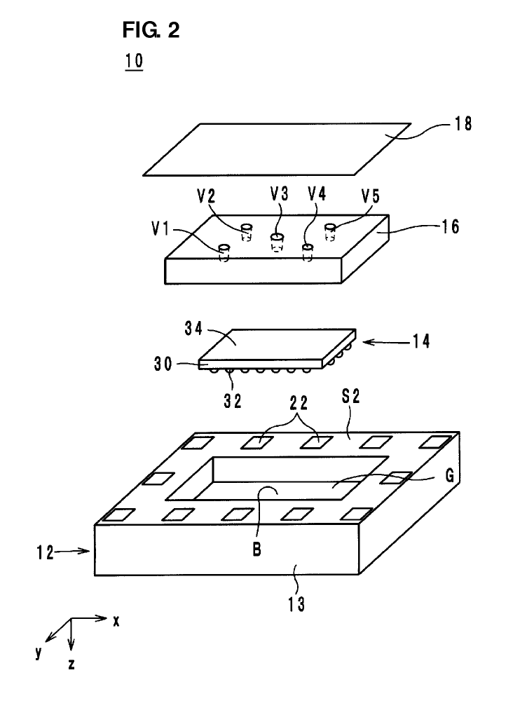

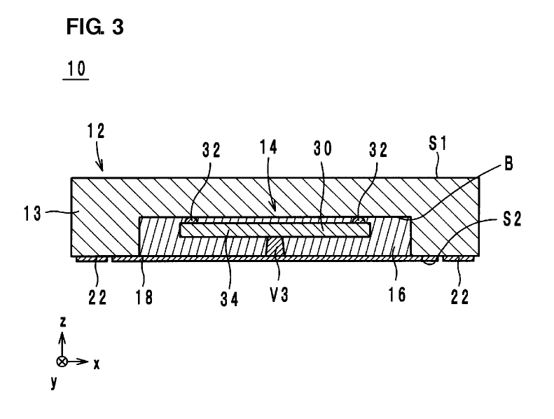

FIG. 1A and FIG. 1B are external perspective views of a circuit module 10 according to a preferred embodiment of the present invention. FIG. 2 is an exploded perspective view of the circuit module 10. FIG. 3 is a cross-sectional structural view taken along line A-A in the circuit module 10 of FIG. 1A. In FIGS. 1A and 1B, FIG. 2, and FIG. 3, a direction perpendicular to the circuit module 10 is defined as a Z-axis direction. In plan view in the Z-axis direction, a direction of a longer side of the circuit module 10 is defined as an X-axis direction, and a direction of a shorter side of the circuit module 10 is defined as a Y-axis direction.

The circuit module 10 is preferably, for example, a high-frequency module mounted on a motherboard (not shown) and used as a portion of a transmitting circuit of a mobile phone. As illustrated in FIGS. 1A and 1B and FIG. 2, the circuit module 10 preferably includes a circuit board 12, an IC chip (electronic component) 14, an insulating resin 16, a ground electrode 18, chip components 24, and via-hole conductors V1 to V5. The circuit board 12 is preferably, for example, a low temperature co-fired ceramics (LTCC) substrate. The circuit board 12 preferably includes a circuit board body 13, lands 20, and outer electrodes 22. The circuit board body 13 is preferably a substantially plate-shaped multilayer substrate including principal surfaces S1 and S2. The circuit board body 13 preferably includes an electric circuit (not shown) provided therein. The principal surface S1 is located on a more positive side than the principal surface S2 in the Z-axis direction. As illustrated in FIG. 2, the principal surface S2 of the circuit board body 13 preferably includes a recess G. The recess G is preferably a substantially rectangular concave portion in plan view from a negative side in the Z-axis direction, for example. The recess G includes a bottom surface B as illustrated in FIG. 2.

The lands 20 are mount electrodes on the principal surface S1. The outer electrodes 22 are mount electrodes arranged on the principal surface S2 along each side thereof. The outer electrodes 22 are soldered to lands on the motherboard when the circuit module 10 is mounted on the motherboard. Note that only some representative lands 20 and outer electrodes 22 are denoted by reference numerals in FIGS. 1A and 1B, FIG. 2, and FIG. 3.

The IC chip 14 is preferably, for example, a power amplifier in a transmitting circuit of a mobile phone. As illustrated in FIG. 2 and FIG. 3, preferably, the IC chip 14 is mounted inside the recess G and includes an IC substrate 30, bumps 32, and a ground electrode 34. Preferably, the IC substrate 30 is a substantially plate-shaped semiconductor substrate and includes an integrated circuit. The bumps 32 are preferably solder balls, for example, disposed on a principal surface of the IC substrate 30 on the positive side in the Z-axis direction. The IC chip 14 is preferably mounted on lands (not shown) on the bottom surface B of the recess G, with the bumps 32 interposed therebetween. The ground electrode 34 is disposed on a principal surface of the IC substrate 30 on the negative side in the Z-axis direction. A ground potential is applied to the ground electrode 34. As illustrated in FIG. 3, the IC chip 14 having the configuration described above preferably fits in the recess G without protruding therefrom.

The insulating resin 16 is preferably made of, for example, an epoxy resin and is filled into the recess G. That is, the insulating resin 16 is preferably filled into the recess G such that no gap is created between the circuit board body 13 and the IC chip 14. As illustrated in FIG. 3, a surface of the insulating resin 16 on the negative side in the Z-axis direction is preferably flush or substantially flush with a portion of the principal surface S2 other than the recess G. For example, the insulating resin 16 preferably has a thermal conductivity that is less than that of the circuit board body 13.

The ground electrode 18 is preferably a substantially rectangular electrode, for example, disposed over the recess G filled with the insulating resin 16. That is, in plan view from the negative side in the Z-axis direction, the recess G is covered with the ground electrode 18. The ground electrode 18 is preferably soldered to a ground electrode of the motherboard when the circuit module 10 is mounted on the motherboard.

The via-hole conductors V1 to V5 are preferably provided in the insulating resin 16. Specifically, as illustrated in FIG. 2 and FIG. 3, the via-hole conductors V1 to V5 are preferably connecting conductors that pass through the insulating resin 16 in the Z-axis direction. The via-hole conductors V1 to V5 are preferably formed by filling a conductive material into via holes that pass through the insulating resin 16 in the Z-axis direction. The conductive material preferably has a thermal conductivity greater than that of the insulating resin 16.

Preferably, end portions of the via-hole conductors V1 to V5 on the positive side in the Z-axis direction are in contact with the IC chip 14 or, more accurately, are in contact with the ground electrode 34 of the IC chip 14. Preferably, end portions of the via-hole conductors V1 to V5 on the negative side in the Z-axis direction are exposed from the insulating resin 16 or, more accurately, are in contact with the ground electrode 18. This allows the ground electrode 18 and the ground electrode 34 to be electrically connected to each other.

As illustrated in FIG. 2 and FIG. 3, the via-hole conductors V1 to V5 preferably have diameters that increase from the positive side to the negative side in the Z-axis direction, for example. That is, in plan view in the Z-axis direction (i.e., in a direction in which the via-hole conductors V1 to V5 extend), the areas of the end portions of the via-hole conductors V1 to V5 on the negative side in the Z-axis direction are preferably greater than those of the end portions of the via-hole conductors V1 to V5 on the positive side in the Z-axis direction. The end portions of the via-hole conductors V1 to V5 on the negative side in the Z-axis direction preferably have a plurality of different areas, for example. In other words, the via-hole conductors V1 to V5 preferably have a plurality of different diameters. In the circuit module 10, the diameter of the via-hole conductor V3 is preferably greater than that of the via-hole conductors V1, V2, V4, and V5.

The chip components 24 are electronic components, such as a chip coil and a chip capacitor, for example. As illustrated in FIG. 1A, the chip components 24 are mounted on the lands 20 on the circuit board 12 by soldering, for example. The chip components 24, the IC chip 14, and the outer electrodes 22 are electrically connected to each other by the electric circuit provided inside the circuit board body 13.

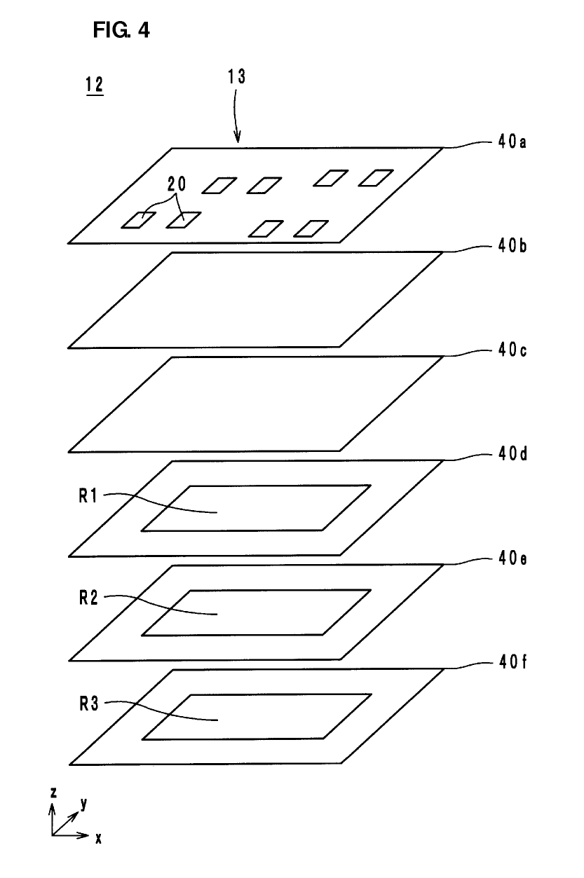

An example of a preferred method for manufacturing the circuit module 10 will now be described with reference to the drawings. FIG. 4 is an exploded perspective view illustrating the circuit board 12 of the circuit module 10. Note that although manufacture of only one circuit board 12 will be described below, in practice, a plurality of circuit boards 12 are simultaneously manufactured.

First, ceramic green sheets 40a to 40f are prepared as illustrated in FIG. 4. The ceramic green sheets 40d to 40f include blank regions R1 and R3, respectively, which are formed into the recess G. The blank regions R1 and R3 are preferably formed by stamping the ceramic green sheets 40d to 40f, for example.

Next, via-hole conductors (not shown) are formed in the ceramic green sheets 40a to 40f. The via-hole conductors define a portion of the electric circuit provided inside the circuit board body 13. The via-hole conductors are formed in accordance with the following procedure. First, via holes are formed by irradiating the ceramic green sheets 40a to 40f with a laser beam at predetermined positions. Next, a conductive material is filled into the via holes.

Then, the lands 20 and a conductor layer are formed on the ceramic green sheets 40a to 40f. The conductor layer defines a portion of the electric circuit inside the circuit board body 13. For example, the lands 20 and the conductor layer are preferably formed by applying conductive paste to the ceramic green sheets 40a to 40f by screen printing.

Next, the ceramic green sheets 40a to 40f are stacked on top of each other, press-bonded, and formed into the unfired circuit board body 13. Then, the unfired circuit board body 13 is fired under predetermined conditions.

Next, as illustrated in FIG. 2 and FIG. 3, the IC chip is mounted on the bottom surface B of the recess G. Specifically, the IC chip 14 is preferably placed on the bottom surface B and subjected to reflow soldering, for example. The bumps 32 are thus secured to the lands on the bottom surface B. Then, the insulating resin 16 is filled into the recess G. Thus, the IC chip 14 is securely attached inside the recess G.

Next, the via-hole conductors V1 to V5 are formed in the insulating resin 16. Specifically, via holes are preferably formed by irradiating the insulating resin 16 with a laser beam, for example. Then, a conductive material is filled into the via holes.

Next, the ground electrode 18 and the outer electrodes 22 are preferably formed on the principal surface S2 by applying conductive paste thereto by screen printing, for example. Thus, the manufacture of the circuit module 10 is performed by the process described above.

The circuit module 10 has excellent thermal dissipation performance as described below. Specifically, in the circuit module 10, the end portions of the via-hole conductors V1 to V5 on the positive side in the Z-axis direction are preferably in contact with the IC chip 14, and the end portions of the via-hole conductors V1 to V5 on the negative side in the Z-axis direction are preferably exposed from the insulating resin 16. The conductive material of the via-hole conductors V1 to V5 preferably has a thermal conductivity greater than that of the insulating resin 16. Thus, heat from the IC chip 14 is transferred through the via-hole conductors V1 to V5 and dissipated outside the circuit module 10. Thus, the excellent thermal dissipation performance of the circuit module 10 is obtained.

In particular, in the circuit module 10, the end portions of the via-hole conductors V1 to V5 on the negative side in the Z-axis direction are preferably in contact with the ground electrode 18. Since the ground electrode 18 functions as a heat sink, the excellent thermal dissipation performance of the circuit module 10 is obtained.

Additionally, in the circuit module 10, the IC chip 14 can be securely attached to the circuit board 12. In the hybrid module described in Japanese Unexamined Patent Application Publication No. 11-220226, the thermal conductive resin is provided only between the heat sink and the circuit component. This is because if the recess is entirely filled with the thermal conductive resin, heat from the circuit component is transferred to the inside of the circuit board and deforms the circuit board. To prevent this, an empty space is provided around the circuit component. Therefore, in the recess, the circuit component is not securely attached to the circuit board. As a result, an external shock to the hybrid module may cause a disconnection between the circuit board and the circuit component.

In contrast, in the circuit module 10, the via-hole conductors V1 to V5 enable heat from the IC chip 14 to be dissipated outside the circuit module 10. For this, the insulating resin 16 is preferably made of a resin having a normal thermal conductivity, such as an epoxy resin, for example. Therefore, in the circuit module 10, the insulating resin 16 can be filled around the IC chip 14. Thus, the IC chip 14 can be securely attached by the insulating resin 16 inside the recess G.

Moreover, in the circuit module 10, since the IC chip 14 is covered with the insulating resin 16, a portion at which the IC chip 14 is mounted on the circuit board 12 is not exposed to the outside. Therefore, even in a hot and humid environment, the bumps 32 of the IC chip 14 and the lands on the bottom surface B of the recess G are prevented from being corroded. Thus, it is possible to use the circuit module 10 in a hot and humid environment.

Additionally, whereas the recess of the hybrid module described in Japanese Unexamined Patent Application Publication No. 11-220226 includes a two-step structure, the recess G of the circuit module 10 includes a one-step structure. Therefore, the circuit module 10 can be manufactured more easily than the hybrid module described in Japanese Unexamined Patent Application Publication No. 11-220226.

In the circuit module 10, in plan view in the Z-axis direction, the areas of the end portions of the via-hole conductors V1 to V5 on the negative side in the Z-axis direction are preferably greater than those of the end portions of the via-hole conductors V1 to V5 on the positive side in the Z-axis direction. Therefore, since the area of portions at which the via-hole conductors V1 to V5 are in contact with the ground electrode 18 is large, the thermal dissipation performance of the circuit module 10 is improved.

The IC chip 14 includes a portion at which the amount of heat generation is relatively large and a portion at which the amount of heat generation is relatively small. In the circuit module 10, as described above, the end portions of the via-hole conductors V1 to V5 on the negative side in the Z-axis direction preferably have a plurality of different areas. Specifically, in the circuit module 10, the diameter of the via-hole conductor V3 is preferably greater than that of the via-hole conductors V1, V2, V4, and V5. Therefore, the portion at which the amount of heat generation is relatively large can be brought into contact with the via-hole conductor V3 having a larger diameter, and the portion at which the amount of heat generation is relatively small can be brought into contact with the via-hole conductors V1, V2, V4, and V5 having a smaller diameter. This enables the circuit module 10 to efficiently dissipate heat.

The configuration of the circuit module 10 is not limited to that described in the above preferred embodiments. The circuit module 10 may be modified within the spirit and scope of the present invention. For example, the via-hole conductors V1 to V5 may preferably be distributed in a non-uniform density in plan view in the Z-axis direction. In other words, in a surface of the insulating resin 16, the occupancy of the via-hole conductors V1 to V5 per unit area may not be uniform. This means that the distribution density of the via-hole conductors V1 to V5 corresponding to the portion at which the amount of heat generation is relatively large can preferably be made greater than the distribution density of the via-hole conductors V1 to V5 corresponding to the portion at which the amount of heat generation is relatively small. This enables the circuit module 10 to efficiently dissipate heat.

In the circuit module 10, the insulating resin 16 is preferably made of a single material. Alternatively, the insulating resin 16 may preferably be made of two or more different insulating resins, for example. Specifically, the insulating resin 16 may preferably be made of a first insulating resin and a second insulating resin having a thermal conductivity greater than that of the first insulating resin. In the recess G, the first insulating resin is preferably arranged closer to the bottom surface B than the second insulating resin is to the bottom surface B. Thus, heat from the IC chip 14 is dissipated outside the circuit module 10 primarily through the second insulating resin, the via-hole conductors V1 to V5, and the ground electrode 18. As a result, heat from the IC chip 14 is prevented from being transferred through the first insulating resin to the circuit board 12. Thus, the circuit board 12 is prevented from being deformed by heat.

As described above, preferred embodiments of the present invention are applicable to circuit modules, and in particular, provide a circuit module having excellent thermal dissipation performance and in which an electronic component (circuit component) is securely attached to a circuit board.

While preferred embodiments of the present invention have been described above, it is to be understood that variations and modifications will be apparent to those skilled in the art without departing the scope and spirit of the present invention. The scope of the present invention, therefore, is to be determined solely by the following claims.

What is claimed is:

1. A circuit module comprising:
a circuit board including a recess in a principal surface thereof;
an electronic component mounted in the recess;
an insulating resin filled in the recess; and
a via-hole conductor provided in the insulating resin; wherein
a first end of the via-hole conductor is exposed from the insulating resin; and
a second end of the via-hole conductor is in contact with the electronic component.

2. The circuit module according to claim 1, further comprising:
a first ground electrode arranged to cover the recess filled with the insulating resin; wherein
the first end of the via-hole conductor is in contact with the first ground electrode.

3. The circuit module according to claim 1, wherein
the electronic component includes a second ground electrode; and
the second end of the via-hole conductor is in contact with the second ground electrode.

4. The circuit module according to claim 1, wherein in plan view in a direction in which the via-hole conductor extends, an area of the first end of the via-hole conductor is greater than an area of the second end of the via-hole conductor.

5. The circuit module according to claim 1, wherein
a plurality of the via-hole conductors are provided; and
in plan view in a direction in which the via-hole conductors extend, the via-hole conductors are distributed in a non-uniform arrangement.

6. The circuit module according to claim 1, wherein
a plurality of the via-hole conductors are provided; and
the first ends of the plurality of via-hole conductors have a plurality of different areas.

7. The circuit module according to claim 1, wherein
the insulating resin is made of a first insulating resin and a second insulating resin having a thermal conductivity greater than that of the first insulating resin; and
the first insulating resin is arranged closer to a bottom of the recess than the second insulating resin.

8. The circuit module according to claim 1, wherein the via-hole conductor is defined by a conductive material filled into a via hole.
